(19) United States
(12) Patent Application Publication
(10) Pub. No.: US 2018/0090448 A1
(43) Pub. Date: Mar. 29, 2018

(54) SEMICONDUCTOR PACKAGE AND METHOD FOR PREPARING SAME

(71) Applicant: WISOL CO., LTD., Osan-si, Gyeonggi-do (KR)

(72) Inventor: Ji Ho KIM, Osan-si (KR)

(21) Appl. No.: 15/563,226

(22) PCT Filed: Apr. 4, 2016
(86) PCT No.: PCT/KR2016/003446

§ 371 Date: Sep. 29, 2017

(30) Foreign Application Priority Data
Apr. 7, 2015 (KR) 10-2015-0049126

(51) Int. Cl. H01L 23/552; H01L 23/31; H01L 25/16; H01L 23/66; H01L 23/00

(52) U.S. Cl. CPC H01L 23/552; H01L 23/3121; H01L 23/3135; H01L 2924/3025; H01L 23/66; H01L 24/48; H01L 24/91; H01L 25/16

(57) ABSTRACT

A semiconductor package and a method for preparing the semiconductor package. The semiconductor package includes a substrate, a metal terminal which is formed on the substrate, a semiconductor component which is mounted on the substrate, an electromagnetic wave shielding layer which is formed to cover the semiconductor component and comes in direct contact with the metal terminal, and a mold which surrounds the electromagnetic wave shielding layer.

### BACKGROUND

### 1. Technical Field

The present invention relates to a semiconductor package, including a substrate, a metal terminal formed in the substrate, a semiconductor component mounted on the substrate, an electromagnetic wave shielding layer formed to surround the semiconductor component and coming in direct contact with the metal terminal, and a mold surrounding the electromagnetic wave shielding layer and, more particularly, to, a method of manufacturing the semiconductor package.

### 2. Description of Related Art

In this modern society, the use of an electronic device is essential, various electronic devices are explosively used in various fields, and the application fields of the electronic devices become wide due to the development of the digital/semiconductor technology and the development of a precision electronic device. Electromagnetic interference generated from the electronic devices causes a mutual malfunction between precision electronic device and a biological bad influence on the human body in addition to electromagnetic wave noise interference. Accordingly, an electronic energy influence in the eco system is rising as a very serious problem.

In particular, a semiconductor device is commonly disposed by integrating several electrical/electronic devices. In this case, an electromagnetic wave directly radiated or conducted from the electrical/electronic device may generate an obstacle to the reception function of different electronic devices. Accordingly, in the semiconductor device used for a portable terminal that must be reduced in size and integrated, there is a need for a method of effectively shielding electromagnetic interference (EMI) in which the reception of a required electronic signal is hindered by an unnecessary electromagnetic signal or electromagnetic noise.

A conventional EMI shield method includes an EMI shield method of protecting an electronic product against an electromagnetic wave generated when the electronic product is used. In the EMI shield method, as shown in FIG. 1, a metal terminal is exposed on the side of a substrate, a mold is performed, and several sheets of metal films are then formed to implement an EMI shield characteristic.

However, the conventional EMI shield method had problems in that an anti-oxidation layer must be separately formed in the last layer in order to prevent the oxidation of the metal films itself and the visibility of marking implemented by a laser on the mold is deteriorated because the substrate and the metal films are formed near a part to implement the shield characteristic. Furthermore, the conventional EMI shield method had disadvantages in that there is a severe limit to the process, the durability of a product itself is weak, a process cost is high, productivity is low, and an EMI shield effect is not so high.

### SUMMARY OF THE INVENTION

The present invention has been made to solve the above problems occurring in the prior art. In a conventional technology, after a mold surrounding a substrate and parts is formed, a plurality of metal films is used for the EMI shield method, but an object of the present invention is to provide a semiconductor package in which an EMI shield material is implemented within the mold.

Furthermore, an object of the present invention is to provide a semiconductor package in which several methods, such as plating, sputtering and metal spraying, can be used as a method of manufacturing an EMI shield layer for a metal shield, and the EMI shield layer can be formed between a plurality of semiconductor components and can be flat formed on a protection film without a curve.

A semiconductor package according to an embodiment of the present invention for accomplishing the objects includes a substrate, a metal terminal formed in a substrate, a semiconductor component mounted over the substrate, an EMI shield layer formed to surround the semiconductor component and to come in direct contact with the metal terminal, and a mold surrounding the EMI shield layer.

In this case, the semiconductor package according to an embodiment of the present invention further includes a protection film formed on the metal terminal and the semiconductor component by coating, wherein the EMI shield layer is formed to surround the protection film.

Furthermore, in the semiconductor package according to an embodiment of the present invention, the metal terminal is exposed by removing a portion belonging to the protection film and coming into contact with the metal terminal, and the EMI shield layer is formed on the exposed portion of the protection film and comes in direct contact with the exposed metal terminal. In this case, the semiconductor component is a SAW filter.

Furthermore, in the semiconductor package according to an embodiment of the present invention, the EMI shield layer is formed on the semiconductor component at a predetermined specific thickness. The EMI shield layer is formed between two or more semiconductor components and shields EMI between the semiconductor components. The EMI shield layer is flat formed on the semiconductor component without a curve.

Furthermore, in the semiconductor package according to an embodiment of the present invention, the EMI shield layer is a metal film, and the EMI shield layer is formed by at least one method of plating, sputtering, metal spraying and print.

Furthermore, the semiconductor package according to an embodiment of the present invention may further include a ground pad for the ground of the semiconductor component. The metal terminal is connected to the ground pad through a via hole.

Meanwhile, a method of manufacturing a semiconductor package according to an embodiment of the present invention includes the steps of (a) forming a metal terminal in a substrate, (b) mounting a semiconductor component over the substrate, (d) forming an EMI shield layer surrounding the semiconductor component, and (e) forming a mold surrounding the EMI shield layer.

In this case, the method of manufacturing a semiconductor package according to an embodiment of the present invention further includes the step (c) of forming a protection film on the metal terminal and the semiconductor component by coating. In the step (d), the EMI shield layer is formed to surround the protection film.

In this case, in the method of manufacturing a semiconductor package according to an embodiment of the present invention, in the step (c), the metal terminal is exposed by removing a portion belonging to the protection film and coming into contact with the metal terminal. In the step (d), the EMI shield layer is formed on the exposed portion of the protection film and comes in direct contact with the exposed metal terminal.

### Advantageous Effects

The semiconductor package of the present invention can effectively shield electromagnetic wave noise generated between several electronic devices and can attenuate all of types of electromagnetic wave noise of a form in which an electrical signal directly conducts through an electrode and a form in which electromagnetic wave noise is generated in the form of an electromagnetic wave.

Furthermore, the semiconductor package of the present invention can shield electromagnetic wave noise between different electronic devices because the EMI shield layer can be formed on the protection film at a predetermined specific thickness and can be flat formed on the protection film without a curve. Furthermore, the semiconductor package can also shield electromagnetic wave noise generated from a plurality of semiconductor components within the semiconductor package because it is formed between the plurality of semiconductor components.

Furthermore, the semiconductor package of the present invention can improve the visibility of marking implemented on the mold by a laser because the EMI shield layer formed to surround the protection film and a plurality of semiconductor components is included within the mold to implement an EMI shield structure.

### BRIEF DESCRIPTION OF DRAWINGS

FIG. 1 is an exemplary diagram showing the configuration of a conventional semiconductor package.

FIGS. 2a and 2b are exemplary diagrams showing the configuration of a semiconductor package according to an embodiment of the present invention.

FIG. 3 is an exemplary diagram showing a construction in which a metal terminal and a semiconductor component are mounted on the substrate of the semiconductor package according to an embodiment of the present invention.

FIG. 4 is an exemplary diagram showing a construction in which the protection film of the semiconductor package according to an embodiment of the present invention is formed.

FIG. 5 is an exemplary diagram showing a construction in which a portion that belongs to the protection film of the semiconductor package according to an embodiment of the present invention and that comes into contact with the metal terminal has been removed.

FIG. 6 is an exemplary diagram showing a construction in which the EMI shield layer of the semiconductor package according to an embodiment of the present invention is formed.

FIG. 7 is an exemplary diagram showing a construction in which the EMI shield layer of the semiconductor package according to an embodiment of the present invention is formed between a plurality of semiconductor components.

FIG. 8 is an exemplary diagram showing a construction in which the EMI shield layer of the semiconductor package according to an embodiment of the present invention is flat formed without a curve.

FIG. 9 is a flowchart illustrating a method of manufacturing a semiconductor package according to an embodiment of the present invention.

### DETAILED DESCRIPTION OF THE INVENTION

Hereinafter, a ‘semiconductor package’ according to the present invention is described in detail with reference to the accompanying drawing. Embodiments described herein are provided in order for those skilled in the art to easily understand the technological spirit of the present invention, and the present invention is not restricted by the embodiments. Furthermore, contents expressed in the accompanying drawings have been diagrammed to easily describe the embodiments of the present invention and may be different from those that are actually implemented.

Meanwhile, elements described herein are only examples for implementing the embodiments of the present invention. Accordingly, in other implementations of the present invention, different elements may be used without departing from the spirit and scope of the present invention.

Furthermore, an expression that some elements are “included” is an expression of an “open type”, and the expression simply denotes that the corresponding elements are present, but should not be construed as excluding additional elements.

Furthermore, expressions, such as ‘the first’ and ‘the second’, are used to only distinguish between a plurality of elements and do not limit the sequence or other characteristics of the elements.

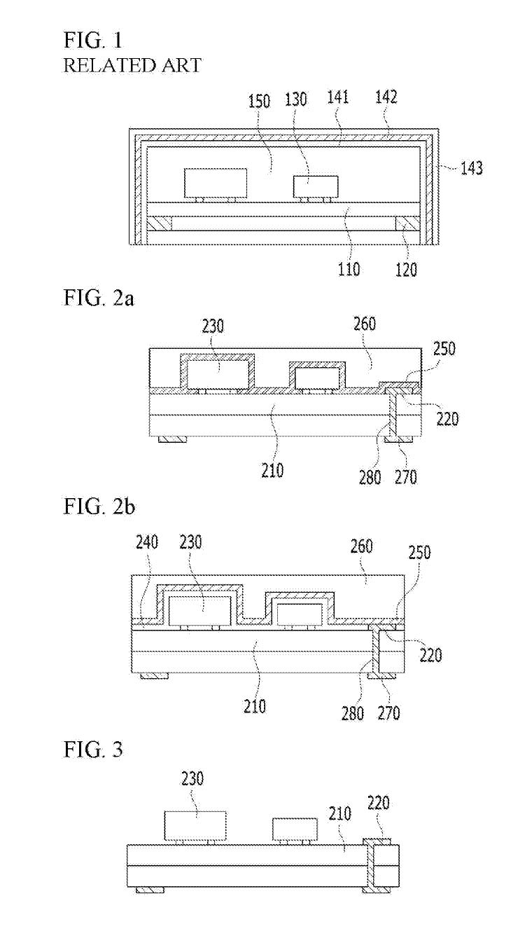

FIG. 1 is an exemplary diagram showing the configuration of a conventional semiconductor package.

Referring to FIG. 1, there is disclosed a method for a conventional semiconductor package to shield electromagnetic waves. In the EMI shield method, first, a semiconductor component 130 is formed over a substrate 110 and metal terminals 120 are exposed on both sides of the substrate 110. Next, a layer that protects the substrate using a mold 150 is formed. Several sheets of metal films, such as a first metal film 141, a second metal film 142 and a third metal film 143 generally surrounding the semiconductor package, are formed to implement an EMI shield characteristic.

In this case, the first metal film is formed to improve an adhesive force between the semiconductor package and the mold. The second metal film is configured for EMI shield. The third metal film is configured to prevent oxidation in the air. The conventional semiconductor package has a problem in that the several sheets of the metal films must be formed.

Furthermore, in the molding of the semiconductor package, pieces of information, such as a firm name, a product, a trademark, a fabrication method, a fabrication date and a fabrication number, are marked on a surface of the semiconductor package in an alphabet or number or symbol using laser marking equipment. In this case, there is a problem in that the visibility and legibility of the marking indicated in the molding are reduced because the several sheets of the metal films functioning as a conventional EMI shield surround all of the surroundings of the semiconductor package.

FIGS. 2a and 2b are exemplary diagrams showing the configuration of a semiconductor package according to an embodiment of the present invention.

Referring to FIGS. 2a and 2b, the semiconductor package of the present invention may include a substrate 210, a metal terminal 220, a semiconductor component 230, a protection film 240, an EMI shield layer 250, a mold 260, a ground pad 270 and a via hole 280.

The substrate 210 is a plate in which electrical circuits whose wires can be changed have been formed, and may include all of a print, a wiring plate and an insulating substrate on a surface of which a conductor pattern can be formed and which are made of an insulating material. Specifically, the substrate of the present invention is preferably formed of a printed circuit board (PCB) or a ceramic substrate.

In this case, the PCB substrate represents an electrical wire that connects circuit components based on a circuit design in the form of a wire figure, and may reproduce an electrical conductor on an insulating matter. Furthermore, electrical components are mounted on the PCB substrate, and wires circuit-connecting the electrical components may be formed in the PCB substrate. The PCB substrate can mechanically fix components having functions other than an electrical connection function.

The metal terminal 220 is formed in the substrate, and the semiconductor component 230 is mounted on the substrate. The metal terminal comes in direct contact with the EMI shield layer 250 and enables the EMI shield layer 250 and the ground pad 270 to be electrically connected. Furthermore, one semiconductor component may be mounted on the substrate and several semiconductor components may be mounted on the substrate at a time depending on the design and performance.

The EMI shield layer 250 is formed to surround the protection film. The EMI shield layer can shield the generation of electromagnetic interference (EMI) and electromagnetic compatibility (EMC).

The electromagnetic interference (EMI) means that an electromagnetic wave directly radiated or conducted from an electrical, electronic device hinders the reception function of the electronic device of another device. Most of facilities and devices using electricity continue to generate some degree of electromagnetic wave noise. Such noise is transferred in the form of an electromagnetic wave radiated through the air or the form of conduction connected through a power line. A communication apparatus, a control apparatus, a computer device and even the human are damaged by EMI. The degree of damage is different depending on the distance from the noise source of EMI, a coupling structure and the strength of a damaged device.

The electromagnetic compatibility (EMC) refers to the capability to prevent noise generated by an electronic device from affecting the operation of another electronic device by reducing the noise and also to enable a device to normally operate by designing the device so that the influence of noise from another electronic device is shielded. In this case, the EMC refers to a method of lowering an obstacle resulting from unwanted electromagnetic interference (EMI), fortuitously generated by an electrical/electronic device and propagated, to a proper level or less.

The EMI affects performance by generating electromagnetic wave coupling in the circuit of a semiconductor package. Accordingly, the semiconductor package of the present invention can reduce EMI by including the element of the EMI shield layer.

The mold 260 is formed to surround the EMI shield layer.

The ground pad 270 is for the ground of the semiconductor component, and the ground pad 270 is connected to the metal terminal 220 through the via hole 280.

Referring to FIG. 2b, the protection film 240 is formed on the metal terminal and the semiconductor component by coating. The metal terminal functions to connect the EMI shield layer for EMI shield and the ground pad. The semiconductor component may include various components which may be used in the semiconductor package, such as a memory semiconductor, a data converter, a diode, a photo semiconductor, an FET, a filter, an amplifier and a matching element.

In particular, the semiconductor component may include a SAW filter. In this case, if the EMI shield layer is directly formed on the SAW filter without the intervention of the protection film, the resin material of the mold 260 permeates between the SAW filter and the substrate, resulting in a product defect. Accordingly, the mold resin and external dust or humidity must be precluded by forming the protection film 240 between the metal terminal and the semiconductor component and the EMI shield layer.

FIGS. 3 to 6 are exemplary diagrams showing constructions in which the metal terminal and the semiconductor component are mounted on the substrate of the semiconductor package according to an embodiment of the present invention, the protection film is formed, a portion coming into contact with the metal terminal is removed, and the EMI shield layer is formed.

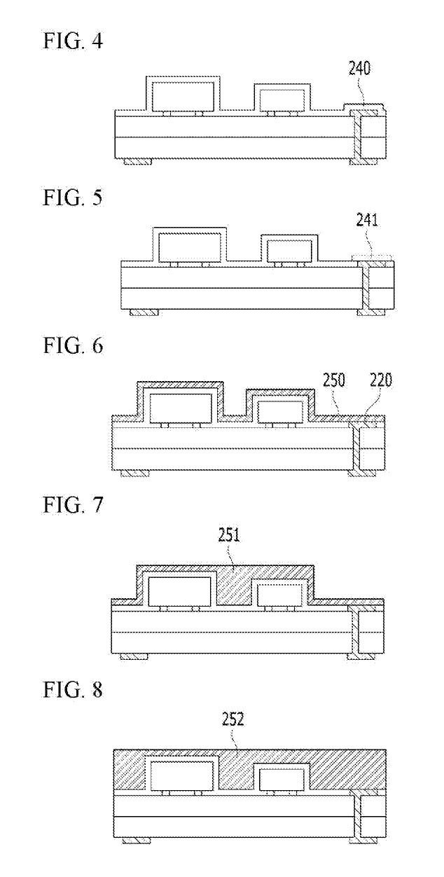

First, as in FIG. 3, the metal terminal 220 and the semiconductor component 230 are formed on the substrate 210. Next, as in FIG. 4, the protection film 240 is formed on the metal terminal 220 and the semiconductor component 230 by coating.

Furthermore referring to, FIG. 5, a portion 241 that belongs to the protection film 240 and that comes into contact with the metal terminal is removed to expose the metal terminal 220. In this case, the portion may be removed using a method of exposing the metal terminal by perforating the protection film.

Next, referring to FIG. 6, the EMI shield layer 250 is formed to surround the protection film. The EMI shield layer may be formed on the protection film at a predetermined specific thickness. In this case, the EMI shield layer is formed on portion through which the metal terminal has been exposed by removing the portion of the protection film that comes into contact with the metal terminal. Accordingly, the metal terminal 220 and the EMI shield layer 250 come in direct contact with each other.

Furthermore, the EMI shield layer may be formed of a metal film. If the metal film is formed as the EMI shield layer, it may be formed using at least one method of plating, sputtering, metal spraying and print.

In the plating, electrical plating in which meal is coated on a surface of the semiconductor package and deposition plating in which a target and metal to be coated are inserted in the vacuum state and volatilized and plated by applying heat may be used.

The sputtering is a kind of a vacuum deposition method. In the sputtering, plasma is collided against a target by accelerating gas, such as ionized argon, in a low degree of vacuum, and atoms are spurted to form a film on a substrate, such as a wafer or glass. The sputtering method is characterized in that has excellent a deposition ability and an alloy maintenance ability and has an excellent ability to deposit refractory metal at a high temperature.

In the print, several sheet printing schemes, such as screen printing and 3D print, may be used.

FIG. 7 is an exemplary diagram showing a construction in which the EMI shield layer of the semiconductor package according to an embodiment of the present invention is formed between a plurality of semiconductor components. FIG. 8 is an exemplary diagram showing a construction in which the EMI shield layer of the semiconductor package according to an embodiment of the present invention is flat formed without a curve.

The EMI shield layer may be formed on the protection film at a predetermined specific thickness while surrounding the protection film as in FIG. 6, and may be formed as in FIGS. 7 and 8.

Referring to FIG. 7, the EMI shield layer may be formed between a plurality of semiconductor components and can shield EMI between the plurality of semiconductor components. In this case, the EMI shield layer may be flat formed without a curve between a semiconductor component and a semiconductor component.

In view of the nature of a recent semiconductor package that has been integrated and reduced in size, a plurality of semiconductor components included in the same semiconductor package mutually generates EMI. In particular, a small-sized semiconductor component may be greatly influenced by the EMI. Accordingly, the EMI shield layer may be formed between the semiconductor components and can effectively shield EMI.

Referring to FIG. 8, the EMI shield layer may be flat formed on the protection film without a curve. In the EMI shield layers of FIGS. 6 and 7, uneven parts are inevitably generated due to a semiconductor component and the metal terminal on the substrate. A curve is obviated by surrounding the uneven parts with a mold. As in FIG. 8, the EMI shield layer may be flat formed without a curve and thus can fundamentally shield EMI.

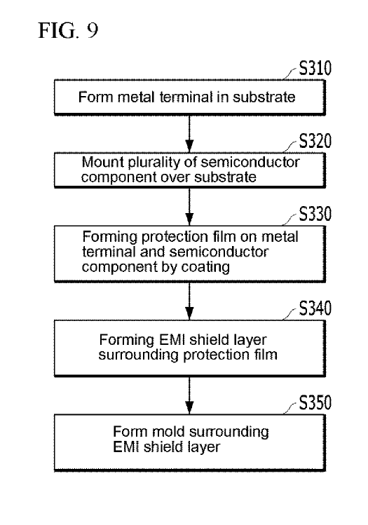

FIG. 9 is a flowchart illustrating a method of manufacturing the semiconductor package according to an embodiment of the present invention.

First, the metal terminal is formed on the substrate (S310). Next, a plurality of semiconductor components is mounted on the substrate (S320). The protection film is formed on the metal terminal and the semiconductor component by coating (S330). The EMI shield layer is formed to surround the protection film (S340). Finally, the mold surrounding the EMI shield layer is formed (S350).

In this case, in the step of forming the protection film by coating, the metal terminal may be exposed by removing a portion coming into contact with the metal terminal, and the EMI shield layer may be formed on the exposed portion of the protection film and thus may come in direct contact with the exposed metal terminal.

The aforementioned embodiments of the present invention have been disclosed for illustrative purposes, and the present invention is not restricted by the embodiments. Furthermore, those skilled in the art to which the present invention pertains may modify and change the present invention in various ways within the spirit and scope of the present invention, and such modifications and changes should be construed as belonging to the range of right of the present invention.

### DESCRIPTION OF REFERENCE NUMERALS

110: conventional substrate

120: conventional metal terminal

130: conventional semiconductor component

141, 142, 143: first, second and third metal films

150: conventional mold

210: substrate

220: metal terminal

230: semiconductor component

240: protection film

241: removed protection film

250, 251, 252: EMI shield layer

260: mold

270: ground pad

280: via hole

1. A semiconductor package comprising:
a substrate;
a metal terminal formed in a substrate;
a semiconductor component mounted over the substrate;
an EMI shield layer formed to surround the semiconductor component and to come in direct contact with the metal terminal; and
a mold surrounding the EMI shield layer.

2. The semiconductor package of claim 1, further comprising a protection film formed on the metal terminal and the semiconductor component by coating,
wherein the EMI shield layer is formed to surround the protection film.

3. The semiconductor package of claim 2, wherein the metal terminal is exposed by removing a portion belonging to the protection film and coming into contact with the metal terminal.

4. The semiconductor package of claim 3, wherein the EMI shield layer is formed on the exposed portion of the protection film and comes in direct contact with the exposed metal terminal.

5. The semiconductor package of claim 2, wherein the semiconductor component is a SAW filter.

6. The semiconductor package of claim 1, wherein the EMI shield layer is formed on the semiconductor component at a predetermined specific thickness.

7. The semiconductor package of claim 1, wherein the EMI shield layer is formed between two or more semiconductor components and shields EMI between the semiconductor components.

8. The semiconductor package of claim 1, wherein the EMI shield layer is flat formed on the semiconductor component without a curve.

9. The semiconductor package of claim 1, wherein the EMI shield layer is a metal film.

10. The semiconductor package of claim 9, wherein the EMI shield layer is formed by at least one method of plating, sputtering, metal spraying and print.

11. The semiconductor package of claim 1, further comprising a ground pad for a ground of the semiconductor component.

12. The semiconductor package of claim 11, wherein the metal terminal is connected to the ground pad through a via hole.

13. A method of manufacturing a semiconductor package, the method comprising steps of:
(a) forming a metal terminal in a substrate;
(b) mounting a semiconductor component over the substrate;
(d) forming an EMI shield layer surrounding the semiconductor component; and
(e) forming a mold surrounding the EMI shield layer.

14. The method of claim 13, further comprising a step (c) of forming a protection film on the metal terminal and the semiconductor component by coating,
wherein in the step (d), the EMI shield layer is formed to surround the protection film.

15. The method of claim 14, wherein in the step (c), the metal terminal is exposed by removing a portion belonging to the protection film and coming into contact with the metal terminal.

16. The method of claim 15, wherein in the step (d), the EMI shield layer is formed on the exposed portion of the protection film and comes in direct contact with the exposed metal terminal.
